(19) United States
(12) Patent Application Publication
(10) Pub. No.: US 2023/0066369 A1
(43) Pub. Date: Mar. 2, 2023

(54) PHOTOVOLTAIC CELL AND PHOTOVOLTAIC MODULE

(71) Applicants: SHANGHAI JINKO GREEN ENERGY ENTERPRISE MANAGEMENT CO., LTD, Shanghai (CN); ZHEJIANG JINKO SOLAR CO., LTD., Haining (CN)

(72) Inventors: Yingli Guan, Zhejiang Providence (CN); Shiliang Huang, Zhejiang Providence (CN); Zhiqiu Guo, Zhejiang Providence (CN); Guohui HAO, Zhejiang Providence (CN); Yuncheng CAO, Zhejiang Providence (CN)

(21) Appl. No.: 17/493,626

(22) Filed: Oct. 4, 2021

(30) Foreign Application Priority Data
Aug. 27, 2021 (CN) 202110998210.4

(51) Int. Cl. H01L 31/0224; H01L 31/02; H01L 31/05

(52) U.S. Cl. CPC H01L 31/022425; H01L 31/05; H01L 31/0201

(57) ABSTRACT

Provided is a photovoltaic cell and a photovoltaic module. The photovoltaic cell includes a substrate; a passivation layer located on at least one surface of the substrate; at least one busbar and at least one finger intersecting with each other on a surface of the substrate. The busbar is electrically connected to the finger. A quantity of the busbar is 10 to 15, and electrode pads arranged on a surface of the substrate. A quantity of the electrode pads is 4 to 6. The electrode pads include first and second electrode pads. The first electrode pads are located on two ends of the busbar, the second electrode pads are located between the first electrode pads. The first electrode pads each have an area of 0.6 mm² to 1.3 mm², and the second electrode pad each have an area of 0.2 mm² to 0.5 mm².

### CROSS-REFERENCE TO RELATED APPLICATIONS

The present application claims priority to Chinese Patent Application No. 202110998210.4, filed on Aug. 27, 2021, the content of which is incorporated herein by reference in its entirety.

### TECHNICAL FIELD

The present disclosure relates to the field of solar energy technologies, and in particular, to a photovoltaic cell and a photovoltaic module.

### BACKGROUND

With the development of technologies, solar devices such as solar modules have become widely applied clean energy supply devices around the world. Generally, a photovoltaic module includes a plurality of photovoltaic cell strings. Each photovoltaic cell string is formed by a plurality of photovoltaic cells connected through a solder strip. A soldering spot is welded to an electrode pad on the photovoltaic cell to play a role of electrical connection. However, the electrode pad on the photovoltaic cell may shield a surface of the photovoltaic cell, thereby affecting light absorption of the photovoltaic cell and then affecting efficiency of the photovoltaic cell.

### SUMMARY

The present disclosure relates to a photovoltaic cell and a photovoltaic module.

Embodiments of the present disclosure relate to a photovoltaic cell. The photovoltaic cell includes: a substrate; a passivation layer located on at least one surface of the substrate; at least one busbar and at least one finger intersecting with each other on a surface of the substrate. The at least one busbar is electrically connected to the at least one finger. A quantity of the at least one busbar is 10 to 15, and a plurality of electrode pads arranged on a surface of the substrate. A quantity of the electrode pad is 4 to 6. The plurality of electrode pads includes first electrode pads and second electrode pads. The first electrode pads are located on two ends of the at least one busbar, the second electrode pads are located between the first electrode pads. The first electrode pads each have an area of 0.6 mm² to 1.3 mm², and the second electrode pad each have an area of 0.2 mm² to 0.5 mm².

In an embodiment, the at least one busbar and/or the at least one finger has a dimension less than or equal to 10 µm along a thickness direction of the photovoltaic cell, and/or the first electrode pads and/or the second electrode pads each have a dimension less than or equal to 8 µm along the thickness direction of the photovoltaic cell.

In an embodiment, the first electrode pads and/or the second electrode pads each have a shape of any one of a rectangle, a rhombus, a circle, an ellipse or combinations thereof.

In an embodiment, the first electrode pads each have a length and a width respectively between 0.3 mm and 1.1 mm.

0009] In an embodiment, the second electrode pads each have a length and a width respectively between 0.4 mm and 0.8 mm.

In an embodiment, each of the second electrode pads is in contact with the at least one busbar and is not in contact with the at least one finger.

In an embodiment, the substrate is an N-type semiconductor.

In an embodiment, the at least one busbar has a width of 20 µm to 45 µm.

In an embodiment, the at least one finger has a width of 20 µm to 40 µm. A quantity of the at least one finger is 80 to 100.

In an embodiment, the substrate is a P-type semiconductor.

In an embodiment, the quantity of the busbar is 10 to 13.

In an embodiment, the at least one busbar has a width of 40 µm to 60 µm.

In an embodiment, the at least one finger has a width of 20 µm to 45 µm. A quantity of the at least one finger is 100 to 150.

The present disclosure further provides a photovoltaic module. The photovoltaic module includes glass, a first film material, a photovoltaic cell string, a second film material, and a back sheet sequentially from a front side to a back side, wherein the photovoltaic cell string includes a plurality of photovoltaic cells, and each of the plurality of photovoltaic cells is the photovoltaic cell according to the above aspect.

In an embodiment, the plurality of photovoltaic cells are connected through an electrode line, and the electrode line has a diameter of 0.25 mm to 0.32 mm.

In an embodiment, the first film material and/or the second film material has a weight of 300 g/m² to 500 g/m².

It is to be understood that the general description above and the detailed description in the following are merely illustrative, which shall not be interpreted as limiting the present disclosure.

### BRIEF DESCRIPTION OF DRAWINGS

FIG. 1 is a schematic structural diagram of a photovoltaic cell according to an embodiment of the present disclosure;

FIG. 2 is a partial enlarged view of Position I in FIG. 1;

FIG. 3 is a schematic structural diagram of a first electrode pad according to an embodiment of the present disclosure;

FIG. 4 is a schematic structural diagram of an embodiment of a second electrode pad according to an embodiment of the present disclosure;

FIG. 5 is a schematic structural diagram of another embodiment of the second electrode pad according to an embodiment of the present disclosure;

FIG. 6 is a schematic structural diagram of yet another embodiment of the second electrode pad according to an embodiment of the present disclosure;

FIG. 7 shows a comparison table of embodiments and the related art according to an embodiment of the present disclosure; and

FIG. 8 is a schematic diagram of a relationship between consumption of silver paste and the number of busbars according to an embodiment of the present disclosure.

### REFERENCE SIGNS

1: busbar; 2: finger; 3: electrode pad; 31 first electrode pad; 32: second electrode pad.

The accompanying drawings herein, which are incorporated in and constitute a part of this specification, illustrate embodiments consistent with the present disclosure and, together with the specification, serve to explain principles of the present disclosure.

### DETAILED DESCRIPTION

In order to better understand the technical solutions of the present disclosure, embodiments of the present disclosure are described in detail below with reference to the accompanying drawings.

It should be made clear that the described embodiments are merely some of rather than all of the embodiments of the present disclosure. All other embodiments acquired by those of ordinary skill in the art without creative efforts based on the embodiments of the present disclosure shall fall within the protection scope of the present disclosure.

The terms used herein in the embodiments of the present disclosure are intended only to describe specific embodiments, and are not intended to limit the present disclosure. As used in the embodiments of the present disclosure and the appended claims, the singular forms of “a/an”, “the”, and “said” are intended to include plural forms, unless otherwise clearly specified by the context.

It is to be understood that the term “and/or” used herein is merely an association relationship describing associated objects, indicating that three relationships may exist. For example, A and/or B indicates that there are three cases of A alone, A and B together, and B alone. In addition, the character “/” herein generally means that associated objects therebefore and thereafter are in an “or” relationship.

It is to be noted that orientation words such as “up”, “down”, “left” and “right” described in the embodiments of the present disclosure are described from the angles as shown in the accompanying drawings and should not be understood as limitations to the embodiments of the present disclosure. In addition, in the context, it is to be further understood that, when one element is connected “above” or “below” another element, it can be directly connected “above” or “below” another element, and can be indirectly connected “above” or “below” the another element through an intermediate element.

With the development of technologies, photovoltaic cells have become common solar devices, and the photovoltaic cells may generally be classified into N-type photovoltaic cells and P-type photovoltaic cells. When energy (for example, heat) is added to pure silicon, several electrons may break away from their covalent bonds and leave atoms. Every time an electron leaves, a hole is left. Then, the electrons may wander around lattices, searching for another hole to settle into. The electrons are called free carriers, which can carry currents. When the pure silicon is mixed with phosphorus atoms, only very little energy is required to allow an “extra” electron of the phosphorus atoms (the outermost five electrons) to escape. When the phosphorus atoms are used for doping, the resulting silicon is N-type, and the solar cell is only partially N-type. The other part of silicon is doped with boron which has only three electrons in its outermost electron layer instead of four, resulting in P-type silicon. The P-type silicon has no free electrons. Phosphorus is diffused on a p-type semiconductor material to form a solar cell of a p/n-type structure, i.e., a P-type silicon wafer. Boron is diffused on an N-type semiconductor material to form a solar cell of an n/p-type structure, i.e., an N-type silicon wafer.

An N-type photovoltaic cell includes an N-type silicon wafer, which uses electrons to conduct electricity. A P-type photovoltaic cell includes a P-type silicon wafer, which uses holes to conduct electricity. Generally, silver paste is provided on two sides of the N-type photovoltaic cell. In one possible implementation, the N-type photovoltaic cell may be a Tunnel Oxide Passivated Contact (TOPCon) cell. A substrate of the TOPCon cell is an N-type semiconductor. The substrate has a back side sequentially provided with a superwave tunnel oxide layer, N-type polycrystalline silicon, a backside passivation layer and a metal electrode, and the other side provided with a boron-doped diffusion layer and a metal electrode.

The P-type photovoltaic cell has one side provided with silver paste and the other side provided with aluminum paste and silver paste in combination. In one possible implementation, the P-type photovoltaic cell may be a Passivated Emitter and Rear Contact (PERC) cell. A substrate of the PERC cell is a P-type semiconductor, and the substrate has a front side provided with a passivation layer and a silver electrode and the other side provided with a passivation layer, an aluminum electrode and a silver electrode.

The N-type photovoltaic cell has a longer service life and higher efficiency. The P-type photovoltaic cell is simple in process and low in cost.

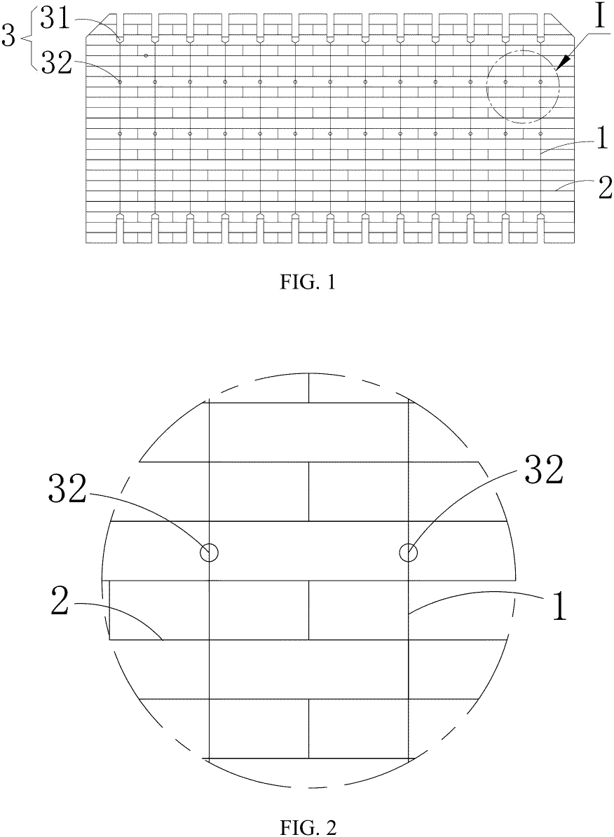

As shown in FIG. 1 and FIG. 2, the present disclosure relates to a photovoltaic cell. The photovoltaic cell includes a substrate and a passivation layer located on a surface of the substrate. The photovoltaic cell converts light energy to electric energy through a PN junction. The PN junction may be manufactured by diffusion to form a diffusion layer. The manufacturing of the passivation layer may increase light conversion efficiency of the photovoltaic cell. The photovoltaic cell further includes a busbar 1 and a finger 2 intersecting with each other on the surface of the substrate. The busbar 1 is electrically connected to the finger 2. The finger 2 is electrically connected to the substrate and configured to collect a current generated by the substrate. The busbar 1 is configured to collect a current from the finger 2. The number of the busbar 1 is 10 to 15, which may be for example 10, 11, 12, 13, 14 or 15. The photovoltaic cell further includes an electrode pad 3 arranged on the surface of the substrate. The number of the electrode pad 3 is 4, 5 or 6. The electrode pad 3 includes first electrode pads 31 and second electrode pads 32. The first electrode pads 31 are located on two ends of the busbar 1. The second electrode pads 32 are located between the first electrode pads 31. The first electrode pad 31 has an area of 0.6 mm² to 1.3 mm², which may be for example 0.6 mm², 0.7 mm², 0.8 mm², 0.9 mm², 1.0 mm², 1.1 mm², 1.2 mm² or 1.3 mm². The second electrode pad 32 has an area of 0.2 mm² to 0.5 mm², which may be for example 0.2 mm², 0.25 mm², 0.3 mm², 0.35 mm², 0.4 mm², 0.45 mm² or 0.5 mm².

The photovoltaic cell according to embodiments of the present disclosure may be applied to solar cells in a size range of 160 mm to 170 mm, which may be applied to, for example, common solar cells with sizes of 161.75 mm, 163.75 mm, 166 mm and the like.

In the existing solution, the number of the busbar 1 is generally 5 to 9. In an embodiment according to the present disclosure, the number of the busbar 1 is set to 10 to 15. An area of a single busbar 1 responsible for current transfer is reduced by increasing the number of the busbar 1 and reducing a spacing between the busbars 1, thereby reducing a current passing through the single busbar 1. Generally, the internal loss of the photovoltaic cell is mainly heat generated during operation. According to a formula Q=I²Rt, where Q is the heat generated during operation, i.e., main internal loss, I is current, R is resistance, and t is operation time. When the current in the circuit decreases, the heat generated is reduced under conditions of constant resistance and fixed operation time, that is, the internal loss is reduced, so as to help improve the overall conversion efficiency of the photovoltaic cell.

Generally, conventional solar cells of a 160+ model are mostly half-cut, provided with seven or more soldering spots. In an embodiment of the present disclosure, the number of the electrode pad 3 of the half-cut photovoltaic cell is reduced to 4 to 6 compared with the conventional solution in the art. Moreover, the first electrode pad 31 has an area set to 0.6 mm² to 1.3 mm², and the second electrode pad 32 has an area of 0.2 mm² to 0.5 mm². The first electrode pads 31 may be arranged on two opposite sides of the busbar 1. The second electrode pads 32 are located between the first electrode pads 31. Since the first electrode pads 31 are located two opposite ends of the busbar 1, the busbar 1 is generally a straight line. Therefore, when the first electrode pad 31 is successfully welded, positions of the busbar 1 and the solder strip are also relatively fixed.

In an embodiment according to the present disclosure, the number of the busbar 1 is increased, and the current to be collected by a single busbar 1 is reduced. Therefore, a width of each busbar 1 may be reduced, and a diameter of an electrode line may be reduced accordingly. Therefore, the number and the area of the electrode pad 3 required are also relatively reduced while a soldering yield and required soldering pull force are ensured, so as to reduce consumption of the silver paste and help to reduce cost.

In an embodiment of the present disclosure, the shielding of the electrode pad 3 for the substrate can be reduced by adjusting the number and the area of the electrode pad 3, so as to reduce the influence of the electrode pad 3 on light absorption of the substrate and improve operation efficiency of the photovoltaic cell. At the same time, when the area of the electrode pad 3 is reduced, consumed silver paste may also be reduced accordingly, thereby reducing the cost.

The electrode pad 3 is set to a shape of a rectangle, a rhombus, a circle, an ellipse or the like, which can reduce the area of the electrode pad 3 compared with a conventional square structure. This design can reduce the shielding for the substrate, and reduce the consumption of the silver paste and reduce the cost.

In one possible implementation solution, the busbar 1 of the photovoltaic cell with an N-type semiconductor substrate has a width of 20 µm to 45 µm, for example, 20 µm, 25 µm, 30 µm, 35 µm, 40 µm, 45 µm or the like.

In one possible implementation solution, the number of the busbar 1 of the photovoltaic cell with a P-type semiconductor substrate is 10, 11, 12 or 13. The busbar 1 has a width of 40 µm to 60 µm, for example, 40 µm, 45 µm, 50 µm, 55 µm, 60 µm or the like.

The number of the busbar 1 is increased by adjusting the width of the busbar 1, which can reduce the shielding of the busbar 1 for the substrate, so as to facilitate the substrate absorbing light, thereby improving the operation efficiency of the photovoltaic cell.

Although the decrease in the width of the busbar 1 may lead to an increase in resistance of a single busbar 1, the increased resistance affects the amount of heat generated less than the decrease of the current. Therefore, the overall amount of heat generated of the photovoltaic cell is still reduced compared with the conventional solution.

In one possible implementation, the busbar 1 and/or the finger 2 have/has a dimension less than or equal to 10 µm along a thickness direction of the photovoltaic cell, and/or the first electrode pad 31 and/or the second electrode pad 32 have/has a dimension less than or equal to 8 µm along the thickness direction of the photovoltaic cell.

Compared with a conventional solution, the busbar 1 and/or the finger 2 is reduced in thickness, so that the busbar 1 and/or the finger 2 is reduced in volume; and/or dimensions of the first electrode pad 31 and the second electrode pad 32 along the thickness direction of the photovoltaic cell are reduced, so that the electrode pad 3 is reduced in volume, which may reduce silver paste materials and reduce manufacturing cost.

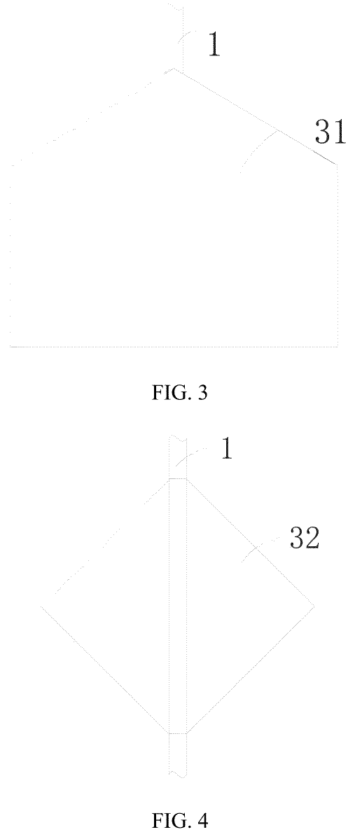

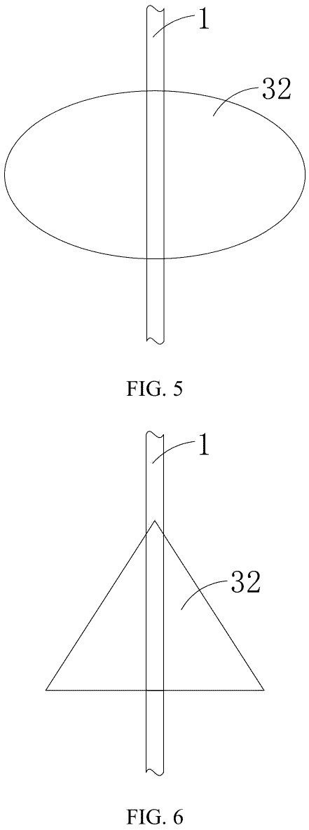

As shown in FIG. 3 to FIG. 6, in one possible implementation, the first electrode pad 31 and/or the second electrode pad 32 is in a shape of one of a rectangle, a rhombus, a circle and an ellipse or combinations thereof.

The setting of the shape of the first electrode pad 31 and/or the second electrode pad 32, while ensuring connection strength, reduces the area and the shielding area, improves operation efficiency and, at the same time, reduces consumption of silver paste and the manufacturing cost.

In one possible implementation, the first electrode pad 31 has a length and a width respectively between 0.3 mm and 1.1 mm, for example, 0.3 mm, 0.4 mm, 0.5 mm, 0.6 mm, 0.7 mm, 0.8 mm, 0.9 mm, 1.0 mm, 1.1 mm, or the like.

In one possible implementation, the second electrode pad 32 has a length and a width respectively between 0.4 mm and 0.8 mm, for example, 0.4 mm, 0.5 mm, 0.6 mm, 0.7 mm, 0.8 mm, or the like.

When the length and the width correspond to the electrode pad 3 in an elliptical shape, a length range corresponds to a major-axis range of the elliptical shape, and a width range corresponds to a minor-axis range of the elliptical shape.

According to the solution, the lengths and the widths of the first electrode pad 31 and the second electrode pad 32 are reduced, which reduces the area of the electrode pad 3 on the premise of sufficient connection strength, reduces the consumption of the silver paste, lowers the manufacturing cost, and reduces the shielding area of the electrode pad 3, thereby improving the operation efficiency of the photovoltaic cell.

In one possible implementation, the second electrode pad 32 is in contact with the busbar 1 and is not in contact with the finger 2. That is, the second electrode pad 32 is not arranged at a position where the first electrode pad 31 and the second electrode pad 32 are connected to each other.

This design can reduce the possibility that normal use of the photovoltaic cell is affected by busbar breakage at a position of connection between the busbar 1 and the finger 2 caused by soldering, which is more in line with actual use requirements.

In one possible implementation solution, the finger 2 of the photovoltaic cell with the N-type semiconductor substrate has a width of 20 µm to 40 µm. The number of the finger 2 is 80 to 100, for example, 80, 90 or 100. The width of the busbar 1 may be the same as the finger 2.

In one possible implementation solution, the finger 2 of the photovoltaic cell with the P-type semiconductor substrate has a width of 20 µm to 45 µm. T number of the finger 2 is 100 to 150, for example, 110, 120, 130, 140, 150 or the like.

In one possible implementation, the P-type photovoltaic cell may have a front surface provided with 109 to 123 fingers 2 and a back surface provided with 123 to 139 fingers 2. Silver, which is expensive, is used on the front surface of the P-type photovoltaic cell to conduct electricity. Therefore, the number of the finger 2 may be reduced appropriately, and aluminum, which is less expensive, and a small amount of silver are used on the back surface to conduct electricity. Therefore, the number of the finger 2 may be appropriately increased on the back surface to improve the operation efficiency of the photovoltaic cell.

In the solution according to an embodiment of the present disclosure, the shielding of the finger 2 for the substrate can be reduced by reducing the number of the finger 2, so as to facilitate the substrate absorbing light and improve the operation efficiency of the photovoltaic cell.

Compared with the conventional solution, according to the present disclosure, the busbar 1 has a narrower width and a larger quantity, the electrode pad 3 has a smaller quantity (a smaller number of soldering pads), and the electrode pad 3 has a smaller area, which can reduce the consumption of the silver paste and help reduce the cost.

The present disclosure relates to a photovoltaic module. The photovoltaic module includes glass, a first film material, a photovoltaic cell string, a second film material, and a back sheet sequentially from front to back, wherein the photovoltaic cell string includes a plurality of photovoltaic cells, and the photovoltaic cell is the photovoltaic cell described in any item above.

The glass on the front surface of the photovoltaic cell protects and transmits light. The first film material and the second film material are configured to bond and fix the glass and the photovoltaic cell string. The photovoltaic cell string is configured to convert light energy into electric energy. The back sheet has functions of sealing, insulation and water resistance.

In one possible implementation, the photovoltaic cells are connected through an electrode line. The electrode line has a diameter of 0.25 mm to 0.32 mm, for example, 0.25 mm, 0.26 mm, 0.27 mm, 0.28 mm, 0.29 mm, 0.30 mm, 0.31 mm, 0.32 mm or the like.

Compared with the existing solution, a thinner electrode line is used, and an area of shielding of the solder strip for the cell is reduced, which improves the operation efficiency of the cell.

In one possible implementation, the electrode line may be partially flattened to form a flat structure at a position where the electrode line corresponds to the electrode pad 3. This design can increase a contact area between the electrode line and electrode pad 3 when the electrode line is in contact with the electrode pad 3. In another possible implementation, the flat structure is formed at a position where the electrode line corresponds to the first electrode pad 31, because the first electrode pad serves as a main electrode pad.

In one possible implementation, the first film material and/or the second film material have/has a weight of 300 g/m² to 500 g/m².

Compared with the existing solution, in an embodiment according to the present disclosure, less silver paste is consumed, the electrode line is thinner, the electrode line is less reduced, the electrode line is less likely to puncture the film material, and thus the first film material and/or the second film material with less grammage, for example, ethylene vinyl acetate (EVA) or polyolefin elastomer (POE), may be selected, so as to reduce the manufacturing cost.

It is to be noted herein that the data exemplified in the present disclosure are only preferred and common data within the data range according to an embodiment of the present disclosure, and the rest is not listed. However, data within the data range according to the present disclosure can achieve the corresponding technical effect.

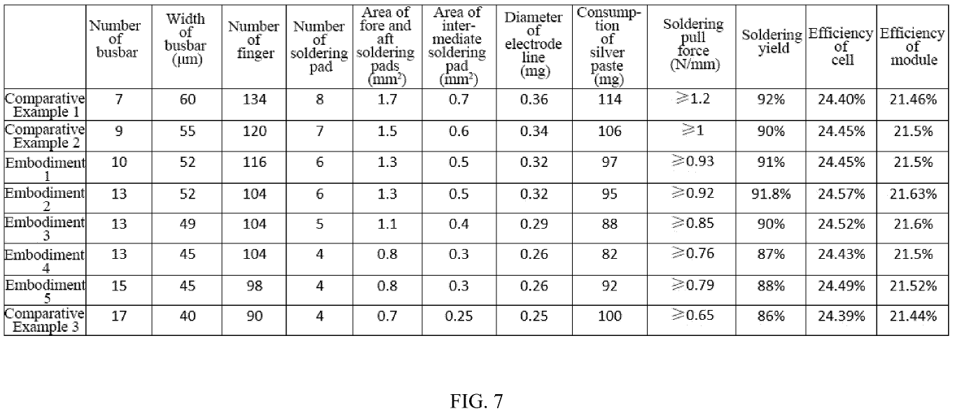

As shown in FIG. 7, the following table is obtained upon test. The embodiments are solutions according to the present disclosure, which are specifically technical effects achieved by a 163 cell, and the comparative examples are existing conventional solutions. It may be obtained from Comparative Example 1, Comparative Example 2 and Embodiment 1 to Embodiment 5 that, the number of the finger 2 may be reduced when the number of the busbar 1 is increased, and the current to be collected by a single busbar 1 is reduced when the number of the busbar 1 is increased. Therefore, a width of each busbar 1 may be reduced, and the diameter of the electrode line may be reduced at the same time. Therefore, the number and the area of the electrode pad 3 required are also relatively reduced while a soldering yield and required soldering pull force are ensured, so as to effectively reduce cost. Generally, processing requirements may be met when a minimum value of the soldering pull force is greater than 0.75 N. It may be known from the table that compared with Comparative Examples 1 and 2, Embodiments 1 to 5 can still meet the requirements of the soldering pull force while reducing the consumption of the silver paste and reducing the cost, which has a soldering yield fluctuating slightly, so as to meet actual use requirements. At the same time, it may be obtained from the data in the table that, compared with the comparative examples, the embodiments further improve the efficiency of the cell and the efficiency of the module while reducing the cost, which is more in line with the actual use requirements.

It may be obtained from Embodiments 2 to 4 that, when the number of the busbar 1 and the number of the finger 2 are fixed, if the width of the busbar 1 is smaller, the number of the soldering spot is smaller, the area is smaller, and less silver paste is consumed. At the same time, the width of the busbar 1 is reduced, and the diameter of the electrode line may also be relatively reduced. Therefore, less silver paste is consumed.

It may be obtained from Embodiments 4 and 5 that, when the area of the electrode pad 3 is fixed, even if the number of the finger 2 is reduced, the consumption of the silver paste may also be increased due to the increase in the number of the busbar 1. Therefore, the number of the busbar 1 has greater influence on the consumption of the silver paste than the number of the finger 2.

In the solution according to the present disclosure, the number of the busbar 1 ranges from 10 to 15. When the number of the busbar 1 exceeds 15, it may be obtained from Embodiments 1 to 5 and Comparative Example 3 that, in Comparative Example 3, the number of the busbar 1 is increased, the width is reduced, and the area of the soldering spot is reduced. In this case, although the number of the finger 2 is reduced, the consumption of the silver paste is increased due to an excessive number of the busbar 1. Moreover, the soldering pull force cannot meet the processing requirements, and the efficiency of the cell and the efficiency of the module are evidently reduced compared with each embodiment, so the cost performance is low in actual use, which does not meet actual manufacturing and use requirements.

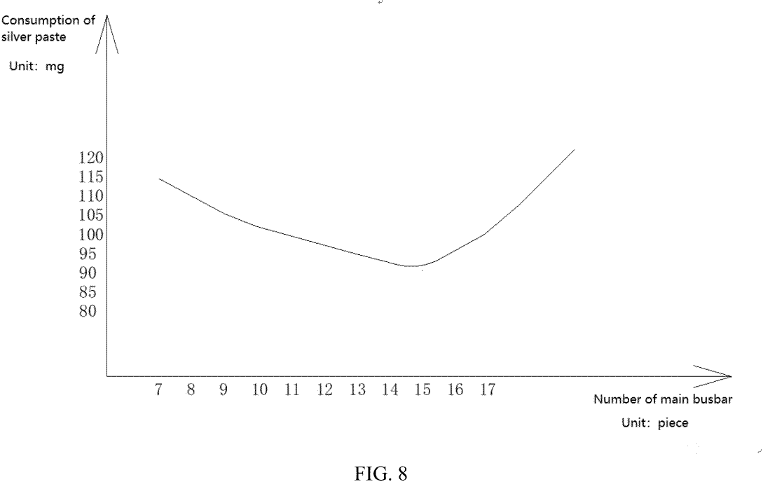

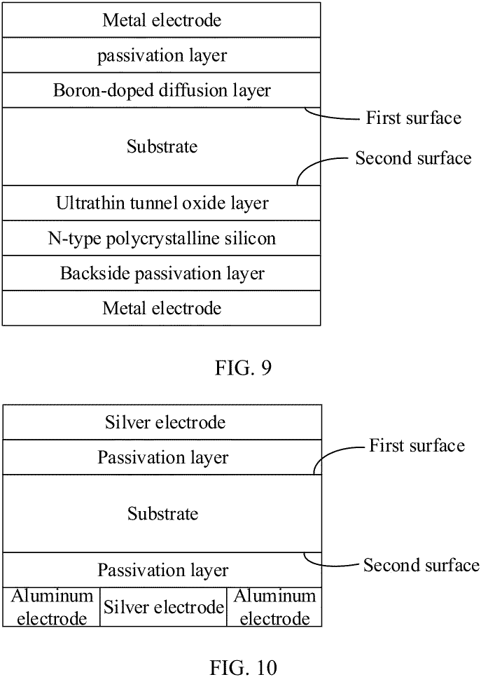

As shown in FIG. 8, with an increase in the number of the busbar 1 and a decrease in the number of the finger 2, a curve of the consumption of the silver paste is an inverse parabola. When the number of the busbar 1 exceeds 15, a reduction in the silver paste caused by the decrease in the number of the finger 2 is less than an increase in the silver paste caused by the increase in the number of the busbar 1. Overall, the consumption of the silver paste increases significantly, which increases the cost, and reduces the soldering yield, and the efficiency of the cell and the efficiency of the module to some extent.

The above are only preferred embodiments of the present disclosure and are not intended to limit the present disclosure. For those skilled in the art, the present disclosure may have various modifications and variations. Any modifications, equivalent substitutions, improvements and the like made within the principle of the present disclosure should fall within the protection scope of the present disclosure.

1. A photovoltaic cell, comprising:
a substrate having a first surface and a second surface, wherein the substrate is an N-type semiconductor; an ultrathin tunnel oxide layer, N-type polycrystalline silicon, a backside passivation layer and a metal electrode are sequentially provided on the first surface; and a boron-doped diffusion layer and a metal electrode are provided on the second surface;
a passivation layer located on at least one of the first surface or the second surface of the substrate;
a plurality of busbars and a plurality of fingers that intersect with each other on the first surface of the substrate, wherein the plurality of busbars is electrically connected to the plurality of fingers, a quantity of the plurality of busbars is 10 to 15, and at least one of the plurality of busbars has a width of 20 µm to 45 µm; and
a plurality of electrode pads arranged on the first surface of the substrate, wherein each of the plurality of busbars is connected to only 4 to 6 electrode pads of the plurality of electrode pads, the 4 to 6 electrode pads including first electrode pads and second electrode pads, wherein the first electrode pads are located on two ends of each of the plurality of busbars, the second electrode pads are located between the first electrode pads, the first electrode pads each having an area of 0.6 mm² to 1.3 mm², and the second electrode pads each having an area of 0.2 mm² to 0.5 mm²; and each of the second electrode pads being in contact with at least one busbar of the plurality of busbars, and being in contact with none of the plurality of fingers of the photovoltaic cell.

2. The photovoltaic cell according to claim 1, wherein at least one of the plurality of busbars or at least one of the plurality of fingers has a dimension less than or equal to 10 µm along a thickness direction of the photovoltaic cell, or
wherein at least one of the first electrode pads or the second electrode pads each have a dimension less than or equal to 8 µm along the thickness direction of the photovoltaic cell.

3. The photovoltaic cell according to claim 1, wherein at least one of the first electrode pads or the second electrode pads each have a shape of any one of a rectangle, a rhombus, a circle, an ellipse or combinations thereof.

4. The photovoltaic cell according to claim 3, wherein the first electrode pads each have a length and a width respectively between 0.3 mm and 1.1 mm.

5. The photovoltaic cell according to claim 3, wherein the second electrode pads each have a length and a width respectively between 0.4 mm and 0.8 mm.

6. (canceled)

7. (canceled)

8. (canceled)

9. The photovoltaic cell according to claim 1, wherein at least one of the plurality of fingers has a width of 20 µm to 40 µm; and
a quantity of the plurality of fingers is 80 to 100.

10. (canceled)

11. (canceled)

12. (canceled)

13. (canceled)

14. A photovoltaic module, comprising glass, a first film material, a photovoltaic cell string, a second film material, and a back sheet sequentially from a front side to a back side, wherein the photovoltaic cell string comprises a plurality of photovoltaic cells, and each of the plurality of photovoltaic cells comprises:
a substrate having a first surface and a second surface, wherein the substrate is an N-type semiconductor;
an ultrathin tunnel oxide layer, N-type polycrystalline silicon, a backside passivation layer, and a metal electrode provided on the first surface of the substrate;
a boron-doped diffusion layer and a metal electrode provided on the second surface of the substrate;
a passivation layer located on at least one of the first surface or the second surface of the substrate;
a plurality of busbars and a plurality of fingers that intersect with each other on the first surface of the substrate, wherein the plurality of busbars are electrically connected to the plurality of fingers, a quantity of the plurality of busbars is 10 to 15, and at least one of the plurality of busbars has a width of 20 µm to 45 µm; and
a plurality of electrode pads arranged on the first surface of the substrate, wherein each of the plurality of busbars is connected to only 4 to 6 electrode pads of the plurality of electrode pads, the 4 to 6 electrode pads including first electrode pads and second electrode pads, wherein the first electrode pads are located on two ends of each of the plurality of busbars, the second electrode pads are located between the first electrode pads, the first electrode pads each having an area of 0.6 mm² to 1.3 mm², and the second electrode pads each having an area of 0.2 mm² to 0.5 mm²; and each of the second electrode pads being in contact with the at least one busbar of the plurality of busbars, and being in contact with none of the plurality of fingers of the photovoltaic cell.

15. The photovoltaic module according to claim 14, wherein the plurality of photovoltaic cells are connected through an electrode line, and the electrode line has a diameter of 0.25 mm to 0.32 mm.

16. The photovoltaic module according to claim 14, wherein at least one of the first film material or the second film material has a weight of 300 g/m² to 500 g/m².

17. The photovoltaic module according to claim 14, wherein at least one of the plurality of busbars or at least one of the plurality of fingers has a dimension less than or equal to 10 µm along a thickness direction of the photovoltaic cell, or
wherein at least one of the first electrode pads or the second electrode pads each have a dimension less than or equal to 8 µm along the thickness direction of the at least one photovoltaic cell.

18. The photovoltaic module according to claim 14, wherein the first electrode pads each have a length and a width respectively between 0.3 mm and 1.1 mm.

19. The photovoltaic module according to claim 14, wherein the second electrode pads each have a length and a width respectively between 0.4 mm and 0.8 mm.

20. The photovoltaic module according to claim 14, wherein the quantity of the plurality of busbars is 10 to 13.

21. A photovoltaic cell, comprising:
a substrate having a first surface and a second surface, wherein the substrate is a P-type semiconductor;
a passivation layer and a silver electrode are provided on the first surface of the substrate; and a passivation layer, an aluminum electrode, and a silver electrode are provided on the second surface of the substrate;
a passivation layer located on at least one of the first surface or the second surface of the substrate;
a plurality of busbars and a plurality of fingers that intersect with each other on the first surface of the substrate, wherein the plurality of busbars is electrically connected to the plurality of fingers, a quantity of the plurality of busbars is 10 to 15, and at least one of the plurality of busbars has a width of 40 µm to 60 µm; and
a plurality of electrode pads arranged on the first surface of the substrate, wherein each of the plurality of busbars is connected to only 4 to 6 electrode pads of the plurality of electrode pads, the 4 to 6 electrode pads including first electrode pads and second electrode pads, wherein the first electrode pads are located on two ends of each of the plurality of busbars, the second electrode pads are located between the first electrode pads, the first electrode pads each having an area of 0.6 mm² to 1.3 mm², and the second electrode pads each having an area of 0.2 mm² to 0.5 mm²; and each of the second electrode pads being in contact with the at least one busbar of the plurality of busbars, and being in contact with none of the plurality of fingers of the photovoltaic cell.

22. The photovoltaic cell according to claim 21, wherein the quantity of the plurality of busbars is 10 to 13.

23. The photovoltaic cell according to claim 21, wherein at least one finger of the plurality of fingers has a width of 20 µm to 45 µm; and
a quantity of the plurality of fingers is 100 to 150.

24. A photovoltaic module comprising glass, a first film material, a photovoltaic cell string, a second film material, and a back sheet sequentially from a front side to a back side, wherein the photovoltaic cell string comprises a plurality of photovoltaic cells according to claim 21.

25. The photovoltaic module according to claim 24, wherein the plurality of photovoltaic cells are connected by an electrode line having a diameter of 0.25 mm to 0.32 mm.

26. The photovoltaic module according to claim 24, wherein the first film material or the second film material has a weight of 300 g/m² to 500 g/m².

27. The photovoltaic module according to claim 24, wherein at least one of the plurality of busbars or at least one of the plurality of fingers has a dimension less than or equal to 10 µm along a thickness direction of the photovoltaic cell, or
the first electrode pads or the second electrode pads each have a dimension less than or equal to 8 µm along the thickness direction of the photovoltaic cell.
